(19) United States
(12) Patent Application Publication
(10) Pub. No.: US 2016/0318756 A1
(43) Pub. Date: Nov. 3, 2016

(54) PROCESS FOR MANUFACTURING SEMICONDUCTOR PACKAGE HAVING HOLLOW CHAMBER

(71) Applicant: CHIPBOND TECHNOLOGY CORPORATION, Hsinchu (TW)

(72) Inventors: Cheng-Hung Shih, Changhua County (TW); Yung-Wei Hsieh, Hsinchu City (TW); Shu-Chen Lin, Pingtung County (TW); Fu-Yen Ho, Hsinchu County (TW); Yen-Ting Chen, Hsinchu City (TW)

(21) Appl. No.: 14/736,328

(22) Filed: Jun. 11, 2015

(30) Foreign Application Priority Data
May 1, 2015 (TW) 104114011

(51) Int. Cl. B81C 1/00

(52) U.S. Cl. CPC B81C 1/00238; B81C 2203/035

(57) ABSTRACT

A process for manufacturing a semiconductor package having a hollow chamber includes providing a bottom substrate having a bottom plate, a ring wall and a slot, wherein the ring wall and the bottom plate form the slot; forming an under ball metallurgy layer on a surface of the ring wall;

bumping a plurality of solder balls on a surface of the under ball metallurgy layer, each of the solder balls comprises a diameter, wherein a spacing is spaced apart between two adjacent solder balls; performing reflow soldering to the solder balls for making the solder balls melting and interconnecting to form a connection layer; connecting a top substrate to the bottom substrate, wherein the lot of the bottom substrate is sealed by the top substrate to form a hollow chamber used for accommodating an electronic device.

### FIELD OF THE INVENTION

The present invention is generally relating to a process for manufacturing a semiconductor package. The invention particularly represents the process for manufacturing a semiconductor package having hollow chamber.

### BACKGROUND OF THE INVENTION

MEMS package process uses a substrate (Silicone substrate or other semiconductor material) forming a cavity by wet etching, dry etching or electrical discharge machining; mounting electronic devices (such as resistor, transistor, radio frequency apparatus, semiconductor circuit or capacitor) desired for package in the cavity; and eventually covering the substrate with a case to complete package. MEMS package apparatus is often utilized in consuming electronic products (smart phone or laptop) and has more requirement on the size. Therefore, it will be a critical issue on how to shrink the size of package apparatus for MEMS package process.

In prior art, the conventional method for joining between the case and the substrate is to coat a solder paste on a connection portion of the substrate by screen printing; next laminating the case and the substrate for mutual connection. However, screen printing is to make the solder paste passing through a halftone screen and then forming on the connection portion. When the substrate form the cavity, a relative larger width must be remained by the connection portion of the substrate for offering screen printing to proceed with solder paste coating thus constraining the space in the cavity of the substrate. Therefore, the size of the package apparatus can not be decreased. Besides, the adhesiveness and mobility of the solder paste must take into consideration by way of using printing screen to make the solder paste print onto the connection portion of the substrate smoothly. Thus it is difficult to change composition and proportion of the solder paste along with various requirements.

### SUMMARY

The primary object of the present invention is to make plural solder balls forming on a surface of a ring wall of a bottom substrate, then reflow soldering the solder balls to form a connection layer for making a top substrate and the bottom substrate mutually connected via the connection layer.

A process for manufacturing a semiconductor package having a hollow chamber includes: providing a bottom substrate having a bottom plate, a ring wall and a slot, wherein the bottom plate forms the ring wall, the ring wall comprises a surface, and the ring wall and the bottom plate form the slot; forming a first under ball metallurgy layer on the surface of the ring wall, wherein the first under ball metallurgy layer comprises a surface; disposing a plurality of solder balls on the surface of the first under ball metallurgy layer, wherein each of the solder balls comprises a diameter, wherein a spacing is spaced apart between two adjacent solder balls, and the spacing is not smaller than half the diameter of each of the solder balls; performing reflow soldering to the solder balls for making the solder balls melting and interconnecting to form a connection layer, wherein the connection layer covers the surface of the first under ball metallurgy layer; and connecting a top substrate to the bottom substrate, wherein the top substrate comprises a connection surface connected to the connection layer, wherein the slot of the bottom substrate is sealed by the top substrate to form a hollow chamber for accommodating an electronic device.

In this invention, the connection layer is formed by reflow soldering the solder balls to connect the bottom substrate and the top substrate therefore forming the sealed accommodating chamber for accommodating the electronic device. Owing to micro meter level of the diameter of the solder balls, the width of the ring wall of the bottom substrate is effectively thinned to shrink the size of whole package structure. In addition, owing to the composition and proportion of the solder balls are known, the composition of the solder ball is selected upon requirements from various applications.

### DESCRIPTION OF THE DRAWINGS

FIG. 1 is a flow chart illustrating a process for manufacturing a semiconductor package having a hollow chamber in accordance with a first embodiment of the present invention.

FIG. 2 is a lateral section view illustrating the process for manufacturing the semiconductor package having the hollow chamber in accordance with the first embodiment of the present invention.

FIG. 3 is a lateral section view illustrating the process for manufacturing the semiconductor package having the hollow chamber in accordance with the first embodiment of the present invention.

FIG. 4 is a lateral section view illustrating the process for manufacturing the semiconductor package having the hollow chamber in accordance with the first embodiment of the present invention.

FIG. 5 is a top view illustrating the process for manufacturing the semiconductor package having the hollow chamber in accordance with the first embodiment of the present invention.

FIG. 6 is a lateral section view illustrating the process for manufacturing the semiconductor package having the hollow chamber in accordance with the first embodiment of the present invention.

FIG. 7 is a lateral section view illustrating the process for manufacturing the semiconductor package having the hollow chamber in accordance with the first embodiment of the present invention.

FIG. 8 is a lateral section view illustrating the process for manufacturing the semiconductor package having the hollow chamber in accordance with the first embodiment of the present invention.

FIG. 9 is a lateral section view illustrating the process for manufacturing the semiconductor package having the hollow chamber in accordance with a second embodiment of the present invention.

### DETAILED DESCRIPTION OF THE INVENTION

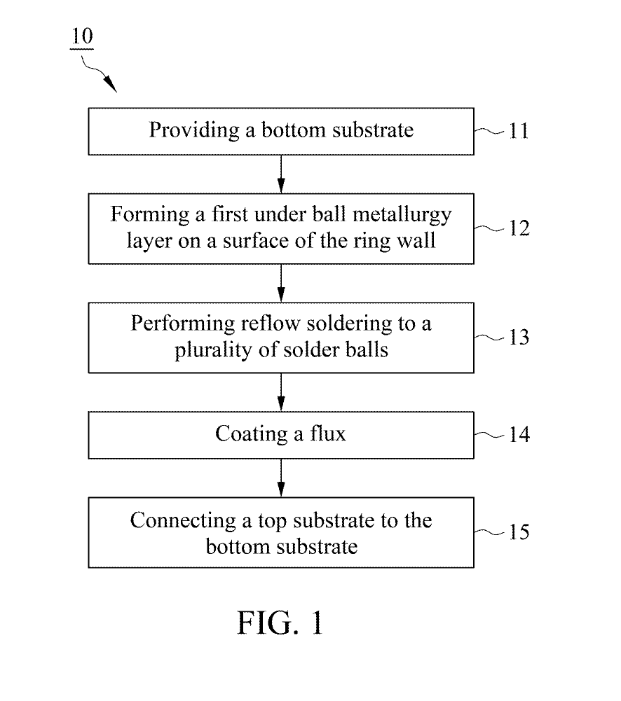

With reference to FIG. 1, a flow chart of process for manufacturing a semiconductor package having a hollow chamber 10 in accordance with a first embodiment of the present invention includes providing a bottom substrate 11; forming a first under ball metallurgy layer on a surface of the ring wall 12; performing reflow soldering to a plurality of solder balls 13; coating a flux 14; and connecting a top substrate to the bottom substrate 15.

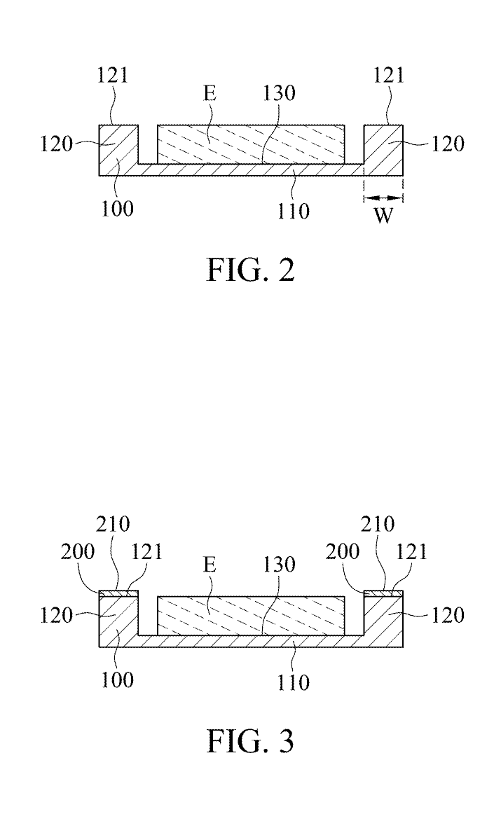

With reference to FIGS. 1, 2 and 5, providing a bottom substrate 100 in step 11, wherein the bottom substrate 100 is selected from one of silicon, ceramic, glass, metal, polymer material or other suitable semiconductor material. The bottom substrate 100 comprises a bottom plate 110, a ring wall 120 and a slot 130, the bottom plate 110 forms the ring wall 120, wherein the ring wall 120 and the bottom plate 110 form the slot 130. The ring wall 120 comprises a surface 121 and a plurality of corners 122, the surface 121 of the ring wall 120 comprises a width W ranged between 8 um to 500 um. In this embodiment, the bottom substrate 100 is formed by wet etching, dry etching or electrical discharge machining mentioned in prior art, and an electronic device E is mounted in the slot 130 of the bottom substrate 100.

With reference to FIGS. 1 and 3, forming a first under ball metallurgy layer 200 on the surface 121 of the ring wall 120 in step 12, wherein the first under ball metallurgy layer 200 comprises a surface 210, and the width of the surface 210 of the first under ball metallurgy layer 200 is substantially the same with the width W of the surface 121 of the ring wall 120. In this embodiment, the first under ball metallurgy layer 200 forms the surface 121 of the ring wall 120 via photoresist process and electroplating/chemical plating, wherein the first under ball metallurgy layer 200 is a multi-layered metal stack structure or alloy structure used for adhesion, moisture and barrier. In this embodiment, the material of the first under ball metallurgy layer 200 includes Ti, Ti/W, Cu, Cr and Ni/V.

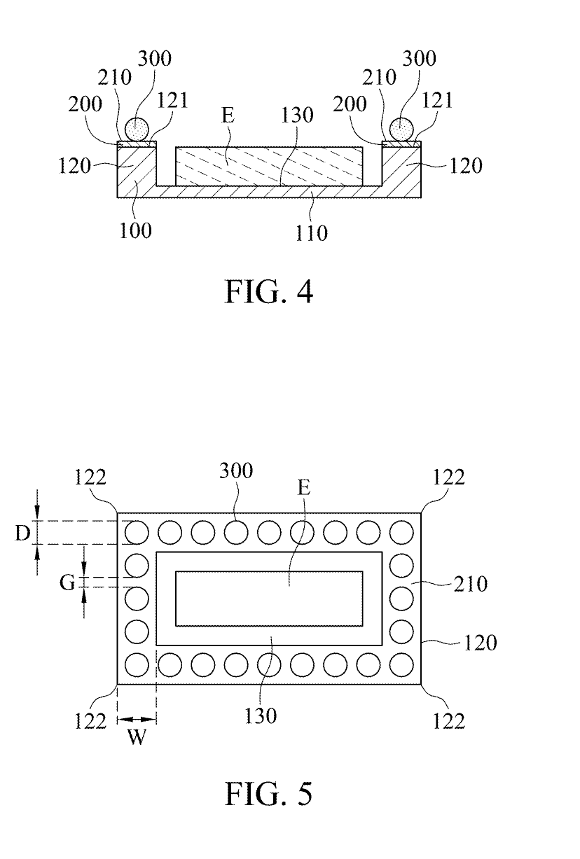

With reference to FIGS. 1, 4 and 5, bumping a plurality of solder balls 300 on the surface 210 of the first under ball metallurgy layer 200, wherein each of the solder balls 300 comprises a diameter D, and a spacing G is spaced apart between two adjacent solder balls 300. The spacing G is not smaller than half the diameter D of each of the solder balls 300 so as to prevent two adjacent solder balls 300 from interference in the ball bumping process. The interference might cause collision and deviation in ball bumping process. Once the spacing G between two adjacent solder balls 300 is overlarge, after reflow soldering process, the two adjacent solder balls 300 are unable to interconnect and will produce small gap. Therefore, with reference to FIG. 5, preferably the ratio between the diameter D of each of the solder balls 300 and the spacing G within two adjacent solder balls 300 ranges between 1:0.5 to 1:3 to assure that two adjacent solder balls 300 are able to connect from each other. Besides, in the reflow soldering process, the overlarge diameter D of the solder ball 300 likely overflows from the surface 210 of the first under ball metallurgy layer 200 and causes short phenomenon of the electronic device E or contamination in whole package structure. Preferably, the ratio between the diameter D of each of the solder balls 300 and the width W of the surface 121 of the ring wall 120 ranges between 1:3 to 1:0.5. In this embodiment, the material of the solder balls 300 is selected from lead free solder ball such as Sn, Bi, Au/Sn, Sn/Ag, Sn/Cu, Sn/Bi, Sn/Ag/Cu, Sn/Ag/Bi, Sn/Ag/Cu/Sb. Owing to the composition and proportion of the solder balls 300 known as material for substrate connection, the composition and proportion of the solder ball 300 are able to select upon requirements. Thus, this invention is widely applicable compared to prior arts.

With reference to FIG. 5, preferably in this embodiment, in the step of bumping a plurality of solder balls 300 on the surface 210 of the first under ball metallurgy layer 200, at least one solder ball 300 is bumped at each of the corners 122 so as to assure that the solder balls 300 after reflow soldering process completely cover the surface 210 of the first under ball metallurgy layer 200.

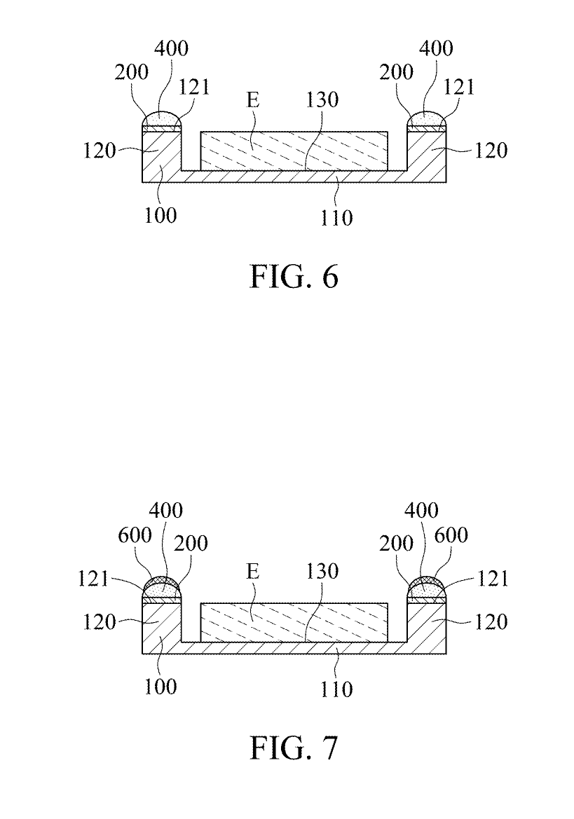

With reference to FIGS. 1 and 6, performing reflow soldering process to the solder balls 300 in step 13 for making the solder balls 300 melting and mutual linked therefore forming a connection layer 400, wherein the connection layer 400 covers the surface 210 of the first under ball metallurgy layer 200. With reference to FIG. 6, due to cohesion tension, the solder balls 300 form spherical surfaces after melting. The larger the diameter D of each of the solder balls 300, the higher the height of the connection layer 300, preferably, the connection layer 400 completely covers the surface 210 of the first under ball metallurgy layer 200 for making the connection between a top substrate and the bottom substrate 100 tightly sealed, wherein the reflow temperature is depend upon the melting point of the solder balls. In this embodiment, the reflow temperature is 0-80 Celsius degrees higher than the melting point of each of the solder balls 300.

For instance, the melting point of SAC is 220 Celsius degrees, the reflow will be performed with reflow temperature between 220 to 300 Celsius degrees to assure that the solder balls 300 are completely melting and make the surface of the connection layer 400 smooth. With reference to FIGS. 1 and 7, coating a flux 600 on the connection layer 400 in step 14 for performing initial cleaning to the surface of the connection layer 400. The cleaning is beneficial for generation of inter-metallic compound once the top substrate is in connection with the bottom substrate 100. Or in the other embodiment, once the surface of the connection layer 400 is able to maintain flatness and clean in the process, or the connection material of the connection layer 400 is selected from one without the flux, or the package is performed in a vacuum chamber (not shown in Fig.) in this invention, the clean step can be ignored, wherein step 15 can be directly performed after performing reflow soldering to the solder balls 300 in step 13.

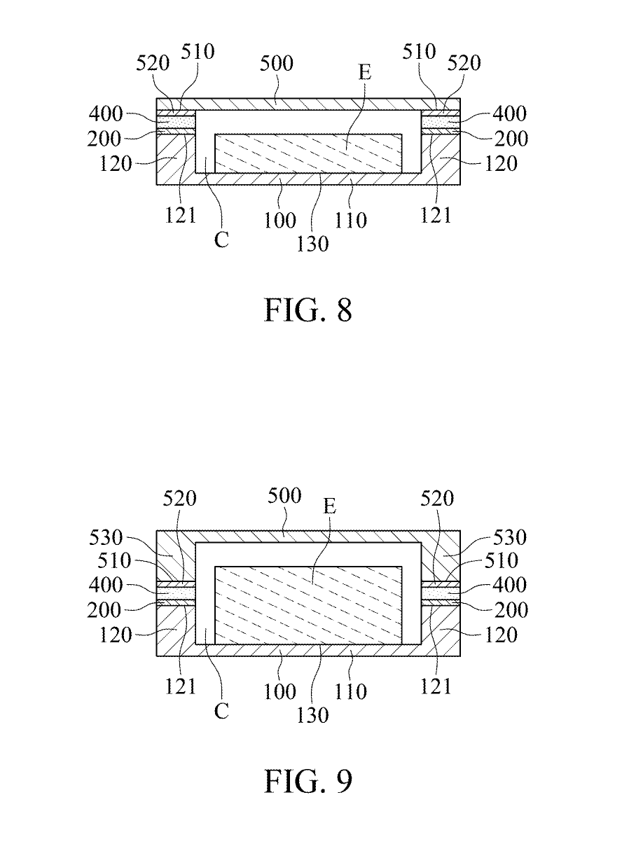

With reference to FIGS. 1 and 8, connecting a top substrate 500 to the bottom substrate 100 via reflow or heat lamination in step 15, wherein the top substrate 500 comprises a connection surface 510 and a second under ball metallurgy layer 520 formed on the connection surface 510. When the top substrate 500 and the bottom substrate 100 are in connection, the second under ball metallurgy layer 520 is in contact with the connection layer 400.

The connection surface 510 connects to the connection layer 400 via the second under ball metallurgy layer 520, wherein the top substrate 500 seals the slot 130 of the bottom substrate 100 to form a hollow chamber C. In step 13, the connection layer 400 completely covers the surface 210 of the first under ball metallurgy layer 200, therefore, the hollow chamber C is completely sealed when the top substrate 500 connects to the bottom substrate 100 via the connection layer 400. Besides, the electronic device E accommodating in the hollow chamber C is completely isolated from outside environment to increase stability of the electronic device E that is under operation.

With reference to FIG. 9, a lateral section view of process for manufacturing a semiconductor package having a hollow chamber 10 in accordance with a second embodiment of the present invention is illustrated. The primary difference between the second embodiment and the first embodiment is that the top substrate 500 comprises a protruding portion 530, and the connection surface 510 is the surface of the protruding portion 530. Thereby, after connecting the top substrate 500 to the bottom substrate 100, the height of the hollow chamber C will be higher and is able to accommodating the electronic device E with higher height or requirement of vertical operation.

In this invention, the top substrate 500 connects with the bottom substrate 100 via the connection layer 400 formed by reflow soldering the solder balls 300 to form the sealed hollow chamber C for accommodating the electronic device E. Owing to micro meter level of the diameter D of the solder balls 300, the width W of the ring wall 120 of the bottom substrate 100 is effectively thinned to shrink the size of whole package structure. In addition, owing to the reason that the composition and proportion of the solder balls 300 are known, the composition of the solder ball 300 is selected upon requirements for various applications.

While this invention has been particularly illustrated and described in detail with respect to the preferred embodiments thereof, it will be clearly understood by those skilled in the art that is not limited to the specific features shown and described and various modified and changed in form and details may be made without departing from the spirit and scope of this invention.

1. A process for manufacturing a semiconductor package having a hollow chamber used for accommodating an electronic device includes:
providing a bottom substrate having a bottom plate, a ring wall formed on the bottom plate, and a slot, wherein the ring wall comprises a surface, wherein the ring wall and the bottom plate define the slot;
forming a first under ball metallurgy layer on the surface of the ring wall, wherein the first under ball metallurgy layer comprises a surface;
bumping a plurality of solder balls on the surface of the first under ball metallurgy layer, wherein each of the solder balls comprises a diameter, wherein a spacing is spaced apart between two adjacent solder balls, and the spacing is not smaller than half the diameter of each of the solder balls;
performing reflow soldering to the solder balls for making the solder balls melting and interconnecting to form a connection layer, wherein the connection layer covers the surface of the first under ball metallurgy layer;
coating a flux onto the connection layer; and
connecting a top substrate to the bottom substrate, wherein the top substrate comprises a connection surface connected to the connection layer, wherein the slot of the bottom substrate is sealed by the top substrate to form a hollow chamber.

2. The process for manufacturing a semiconductor package having a hollow chamber in accordance with claim 1, wherein the ratio between the diameter of each of the solder balls and the spacing within two adjacent solder balls ranges from 1:0.5 to 1:3.

3. The process for manufacturing a semiconductor package having a hollow chamber in accordance with claim 1, wherein the surface of the ring wall comprises a width, and the ratio between the diameter of each of the solder balls and the width of the surface of the ring wall ranges from 1:0.5 to 1:3.

4. The process for manufacturing a semiconductor package having a hollow chamber in accordance with claim 2, wherein the surface of the ring wall comprises a width, and the ratio between the diameter of each of the solder balls and the width of the surface of the ring wall ranges from 1:0.5 to 1:3.

5. The process for manufacturing a semiconductor package having a hollow chamber in accordance with claim 1, wherein the top substrate comprises a second under ball metallurgy layer formed on the connection surface, wherein when the top substrate connects to the bottom substrate, the second under ball metallurgy layer contacts the connection layer.

6. The process for manufacturing a semiconductor package having a hollow chamber in accordance with claim 5, wherein the top substrate comprises a protruding portion, and the connection surface is the surface of the protruding portion.

7. (canceled)

8. The process for manufacturing a semiconductor package having a hollow chamber in accordance with claim 1, wherein the ring wall of the bottom substrate comprises a plurality of corners, wherein in the step of bumping a plurality of solder balls onto the surface of the first under ball metallurgy layer, at least one solder ball is bumped at each of the corners.

9. The process for manufacturing a semiconductor package having a hollow chamber in accordance with claim 1, wherein the connection layer completely covers the surface of the first under ball metallurgy layer.

10. The process for manufacturing a semiconductor package having a hollow chamber in accordance with claim 8, wherein the connection layer completely covers the surface of the first under ball metallurgy layer.

11. The process for manufacturing a semiconductor package having a hollow chamber in accordance with claim 1, wherein the surface of the ring wall comprises a width ranged between 8 um to 500 um.

12. The process for manufacturing a semiconductor package having a hollow chamber in accordance with claim 3, wherein the width of the surface of the ring wall ranged between 8 um to 500 um.

13. The process for manufacturing a semiconductor package having a hollow chamber in accordance with claim 4, wherein the width of the surface of the ring wall ranged between 8 um to 500 um.
